(19) United States
(12) Patent Application Publication
(10) Pub. No.: US 2023/0307561 A1
(43) Pub. Date: Sep. 28, 2023

(54) TYPE-II SUPERLATTICE PHOTODETECTOR WITH LOW-THICKNESS ABSORPTION REGION

(71) Applicant: ZHEJIANG KUN TENG INFRARED TECHNOLOGY CO., LTD., JIAXING (CN)

(72) Inventors: JIAN LONG ZHAN, Coquitlam (CA); YUXIN SONG, JIAXING (CN)

(21) Appl. No.: 17/701,726

(22) Filed: Mar. 23, 2022

(51) Int. Cl. H01L 31/0352; H01L 31/0304; H01L 31/18

(52) U.S. Cl. CPC H01L 31/035236; H01L 31/03046; H01L 31/1844; H01L 31/1864

(57) ABSTRACT

The present invention discloses a type-II superlattice photodetector with a low-thickness absorption region. The absorption region of the type-II superlattice photodetector includes an In(Bi)As layer and a Ga(N)Sb layer. The Bi element content in the In(Bi)As layer is less than 10%, and the Bi element content in the Ga(N)Sb layer is less than 5%. The present invention forms an InBiAs layer and a GaNSb layer by condensing the Bi element into the InAs layer and condensing the N element into the GaSb layer of a traditional InAs/GaSb type-II superlattice photodetector. Therefore, without changing the cut-off wavelength and performance of the detector, periodic and total thicknesses of the type-II superlattice photodetector material can be effectively reduced, and both costs of material use and molecular beam epitaxy can be reduced. In addition, the overall absorption coefficient of the material can be improved, and the volume of the entire device can be reduced.

### TECHNICAL FIELD

The present invention belongs to the technical field of a type-II superlattice photodetector, in particular to a type-II superlattice photodetector with a low-thickness absorption region.

### BACKGROUND

The InAs/GaSb type-II superlattice is featured by a continuously adjustable band gap, which makes it the most potential research object of third-generation infrared detectors. By adjusting thicknesses of barrier and well layers and designing a special material structure, an infrared detector with a continuously variable detection cut-off wavelength of 2-30 μm and a large absorption coefficient can be obtained. The type-II superlattice structure is an intrinsic semiconductor whose performance depends on the minority carrier. The InAs/GaSb type-II superlattice photodetector changes thicknesses of InAs and GaSb layers in a period by adjusting the periodic structure, so that the cut-off wavelength can cover the infrared band of 2.7-30 μm. Effective detection can be achieved for the infrared band within the determined cut-off wavelength only when the InAs/GaSb type-II superlattice photodetector material is grown through molecular beam epitaxy and ensures certain periodic and total thicknesses. If the thickness of the absorption region of the InAs/GaSb type-II superlattice photodetector can be reduced without changing the detection cut-off wavelength and detection precision, the production cost of the InAs/GaSb type-II superlattice photodetector can be effectively reduced.

### SUMMARY

To achieve the aforesaid purpose, the present invention adopts the following technical solution: a type-II superlattice photodetector with a low-thickness absorption region. The absorption region of the type-II superlattice photodetector includes an In(Bi)As layer and a Ga(N)Sb layer. The Bi element content in the In(Bi)As layer is less than 10%, and the Bi element content in the Ga(N)Sb layer is less than 5%.
The structure of the absorption region is as follows:
10 ML InB_{0.05}As_{0.95}/15 ML GaN_{0.05}Sb_{0.95}.
The preparation includes the following steps:
1) epitaxially growing the In(Bi)As layer on a substrate, controlling the Bi element content to be less than 10%, and controlling the thickness of the In(Bi)As layer to 10 ML;
2) growing the Ga(N)Sb layer on the In(Bi)As layer, controlling the Bi element content to be less than 5%, and controlling the thickness of the Ga(N)Sb layer to 15 ML;
3) conducting annealing treatment.

The present invention has the following beneficial effects: The present invention forms an InBiAs layer and a GaNSb layer by condensing the Bi element into the InAs layer and condensing the N element into the GaSb layer of a traditional InAs/GaSb type-II superlattice photodetector. Therefore, without changing the cut-off wavelength and performance of the detector, periodic and total thicknesses of the type-II superlattice photodetector material can be effectively reduced, and the material use cost and the molecular beam epitaxy cost can be reduced. In addition, the overall absorption coefficient of the material can be improved, and the volume of the entire device can be reduced.

### DETAILED DESCRIPTION

A type-II superlattice photodetector with a low-thickness absorption region is provided. The absorption region of the type-II superlattice photodetector includes an In(Bi)As layer and a Ga(N)Sb layer. The Bi element content in the In(Bi)As layer is less than 10%, and the Bi element content in the Ga(N)Sb layer is less than 5%.
The structure of the absorption region is as follows:
10 ML InB_{0.05}As_{0.95}/15 ML GaN_{0.05}Sb_{0.95}.
The type-II superlattice photodetector with a low-thickness absorption region of claim 2, wherein the preparation includes the following steps:
1) epitaxially growing the In(Bi)As layer on a substrate, controlling the Bi element content to be less than 10%, and controlling the thickness of the In(Bi)As layer to 10 ML;
2) growing the Ga(N)Sb layer on the In(Bi)As layer, controlling the Bi element content to be less than 5%, and controlling the thickness of the Ga(N)Sb layer to 15 ML;
3) conducting annealing treatment.

The preferred embodiments of the present invention are described in detail above. It should be understood that those of ordinary skill in the art can make many modifications and changes according to concepts of the present invention without creative efforts. Therefore, all technical solutions that can be obtained by those skilled in the art through logical analysis, inference or limited experiments according to concepts of the present invention on the basis of the prior art should fall within the protection scope defined by the claims.

What is claimed is:

1. A type-II superlattice photodetector with a low-thickness absorption region, wherein the absorption region of the type-II superlattice photodetector includes an In(Bi)As layer and a Ga(N)Sb layer. The Bi element content in the In(Bi)As layer is less than 10%, and the Bi element content in the Ga(N)Sb layer is less than 5%.

2. The type-II superlattice photodetector with a low-thickness absorption region of claim 1, wherein the structure of the absorption region is as follows:
10 ML InB_{0.05}As_{0.95}/15 ML GaN_{0.05}Sb_{0.95}.

3. The type-II superlattice photodetector with a low-thickness absorption region of claim 2, wherein the preparation includes the following steps:
epitaxially growing the In(Bi)As layer on a substrate, controlling the Bi element content to be less than 10%, and controlling the thickness of the In(Bi)As layer to 10 ML;
growing the Ga(N)Sb layer on the In(Bi)As layer, controlling the Bi element content to be less than 5%, and controlling the thickness of the Ga(N)Sb layer to 15 ML;
conducting annealing treatment.
The annealing temperature is 150-300° C.
